(19) United States
(12) Patent Application Publication
(10) Pub. No.: US 2012/0040510 A1
(43) Pub. Date: Feb. 16, 2012

(54) Dicing Before Grinding Process for Preparation of Semiconductor

(76) Inventor: Hoseung Yoo, Cypress, CA (US)

(21) Appl. No.: 13/279,400

(22) Filed: Oct. 24, 2011

Related U.S. Application Data
(63) Continuation of application No. PCT/US2010/032193, filed on Apr. 23, 2010.
(60) Provisional application No. 61/172,404, filed on Apr. 24, 2009.

(51) Int. Cl. H01L 21/78

(52) U.S. Cl. 438/462; 257/E21.599

(57) ABSTRACT

A method for preparing a semiconductor wafer into individual semiconductor dies using both a dicing before grinding operation and a wafer back side adhesive coating includes the step of applying a water or organic solvent soluble material into the partially cut/etched dicing lines and over the top surface of the circuits to prevent the ingress of wafer back side coating into the dicing streets and interference during singulation.

### CROSS-REFERENCE TO RELATED APPLICATIONS

This application is a continuation of International Patent Application No. PCT/US2010/32193 filed Apr. 23, 2010, which claims the benefit of U.S. Provisional Patent Application No. 61/172,404 filed Apr. 24, 2009, the contents of both of which are incorporated herein by reference.

### BACKGROUND OF THE INVENTION

This invention relates to a process for the fabrication of a semiconductor die.

Miniaturization and slimming of electrical and electronic equipment has led to a need for thinner semiconductor dies. In a conventional process for fabricating semiconductor dies, a semiconductor wafer is processed to form a plurality of circuits on the top side of the wafer, and in later steps, the wafer is separated into individual dies, each having at least one circuit on its top side. One way to produce a thinner semiconductor die is to remove excess material from the back side of the wafer, the side without any circuitry, before the wafer is separated.

This removal is typically done by a grinding process and is known as back side grinding, although it can be anticipated that other methods than grinding might be used.

In one method, a protection tape is placed on the top side of the wafer to protect the circuitry, and the back side is thinned by grinding. After grinding, an adhesive tape is laminated to the thinned back side and used to mount the wafer to a frame (the adhesive tape is also known as a mounting tape), which frame holds the wafer during an operation to separate individual dies from the wafer. This separation, also known as singulation, typically is done by sawing the wafer into the individual dies and circuits. One problem with this method is that the thinned wafer is vulnerable to cracking during the sawing operation.

To correct this problem, in another method, dicing lines are partially cut or lasered into the top side of the wafer between adjacent circuits for the purpose of facilitating later dicing. After the dicing lines are cut, a protection tape is laminated to the top side of the wafer, material from the back side of the wafer is removed to the level at which the dicing lines were cut, and the wafer is separated along the dicing lines into individual dies.

The individual dies are used in semiconductor packages or on circuit boards and are attached by adhesive applied after singulation. Applying the adhesive after singulation is not as efficient as applying it onto the wafer before singulation. When the adhesive is applied to the wafer before singulation it is called a wafer back side coating. In this method, a protection tape to protect the circuits is laminated to the top side of the wafer, material from the back side of the wafer is removed to thin the wafer, an adhesive wafer back side coating is applied to the back side of the wafer, the protection tape is removed, and the wafer is diced into individual dies, so that each die contains one of the circuits. However, the same problem as noted above occurs, that is, the thinned wafer is vulnerable to cracking during the dicing operation.

When a wafer back side coating is used, there is a constraint on the use of the partial dicing before grinding method. When dicing lines are partially cut into a wafer, and then a back side coating is applied, the coating will enter and contaminate the dicing lines and dicing streets and interfering with the singulation process. This creates a need for a means of preventing contamination of the wafer back side coating into the dicing lines between the circuits if a partial dicing operation is done before the grinding down operation to thin the wafer.

### SUMMARY OF THE INVENTION

This invention is a method for preparing a semiconductor wafer having a plurality of circuits on the top side of the wafer into individual semiconductor dies comprising the steps of: (1) forming dicing lines into the top side of the wafer between adjacent circuits; (2) applying a water or organic solvent soluble material into the dicing lines and over the top surface of the circuits; (3) laminating a protection layer onto the top side of the wafer and over the hardened water or organic solvent soluble material; (4) thinning the wafer by removing material from the back side of the wafer; (5) applying an adhesive coating to the back side of the wafer; (6) removing the protection tape from the top side of the wafer; (7) removing the water soluble or organic solvent soluble material from the dicing lines between the circuits; and (8) separating the wafer along the dicing lines into individual circuits.

### DETAILED DESCRIPTION OF THE INVENTION

The formation of the plurality of circuits on the top side of the wafer is made according to semiconductor fabrication methods well documented in industry literature. The wafer is a semiconductor material, typically silicon. The circuits can be formed below, on, or above the top surface of the wafer, and can be protected by coatings, such as, passivation layers. These are all referred to herein as the top surface of the wafer.

The dicing lines formed into the top side of the wafer between the individual circuits are also known as dicing streets or trenches. These can be formed prior to or concurrently with the circuit formation. The means for forming the dicing lines include, for example, wet or dry etching, and laser drilling. The purpose of the dicing lines is to facilitate and guide the singulation of the wafer into individual semiconductor dies.

The application of the water soluble or organic solvent soluble chemistry into the dicing lines and over the circuits is done to prevent the ingress of a later applied wafer back side coating. Suitable water soluble materials include hydrophilic polymers such as ionomers, polyvinyl alcohol, water-soluble cellulosics, gelatin, starches and polysaccharides, polyethylene oxides, polyvinyl pyrollidone, sulfonated polystyrenes, and polymers derived from ethylenically unsaturated monomers containing hydrophilic groups. Suitable organic solvent soluble materials include waxes, fluorinated waxes, solid hydrogenated oils, polyolefins, acrylate, methacrylate, and styrenic polymers, and silicone materials (such as, oils, waxes, and polymers). These compounds are dissolved in the appropriate solvent (water or organic solvent) and applied by any effective method, for example, by spin coating, screen or stencil printing, or preferably by spray or jet printing. The concentration of the solution can be high as possible, but to a level that will allow successful application. The water or solvent is then evaporated off before proceeding to the next steps.

The lamination of a protection layer onto the top side of the wafer is done to protect the circuits during the subsequent processing steps and to hold the circuits in place after the wafer is singulated. The protection layer is typically in the form of a tape, and in a particular embodiment, in the form of a UV tape. The adhesive is initially tacky, and then upon irradiation, hardens for ease of release.

Any process effective to thin down the wafer can be used. In a particular embodiment, the back side of the wafer is subjected to a grinding operation. Typically, this back-grinding is done to a level to meet the depth of the dicing lines. In some operations the dicing lines are cut slightly deeper into the front side of the wafer than the target depth of the backside grinding. This slightly over cutting facilitates the eventual singulation of the individual dies.

After the back side grinding operation, the wafer back side coating is applied to the back side of the wafer. The wafer back side coating is an adhesive and is used eventually to attach the individual dies to their substrates. The application of the wafer back side coating is performed by any effective method, such as by spin coating, screen or stencil printing, or spray or jet printing. The chemical composition of the wafer back side coating is any adhesive that will meet the subsequent processing requirements. Such adhesives are known in the art. In one embodiment the wafer back side coating is a B-stageable liquid (“B-stageable” meaning it can be heated to remove solvent and/or to partially cure) that can be applied in any suitable coating method, such as, spin or spray coating, or stencil, screen, or jet printing. The material is then B-staged (heated to remove solvent or be partially cured) to be relatively tack-free at room temperature. In the later die attach operation, the coating can be heated to soften and flow during die attach, and then be heated at an elevated temperature for final cure.

In yet another embodiment the composition of the wafer back side coating is chosen so that it cures to a more brittle state. This brittle state allows the back side coating to be broken (rather than mechanically sawed or lasered) during singulation of the individual dies.

The protection tape from the top side of the wafer is removed.

The water soluble or organic solvent soluble material is removed from the dicing lines between the circuits. If this is a water soluble material, the surface of the wafer is washed with water until all traces of the material are removed. If this is a solvent soluble material, an appropriate solvent for dissolving the material is used.

Finally, the wafer is singulated into individual circuits by separating the wafer along the dicing lines. This separation can be done by sawing with a blade, burning with a laser, by stretching the wafer back side coating if it were provided as a brittle material, or by a combination of partial sawing or laser burning and stretching.

Of particular note in this process is the use of the water soluble or organic solvent soluble material to protect the dicing lines or streets. Inasmuch as this material is filling the dicing streets and covering the surfaces of the circuits, debris from the wafer back side coating cannot contaminate the circuits.

1. A method for preparing a semiconductor wafer having a plurality of circuits on the top side of the wafer into individual semiconductor dies comprising the steps of:
(1) forming dicing lines into the top side of the wafer between adjacent circuits;
(2) applying a water or organic solvent soluble material into the dicing lines and over the top surface of the circuits;
(3) laminating a protection layer onto the top side of the wafer and over the water or organic solvent soluble material;
(4) thinning the wafer by removing material from the back side of the wafer;
(5) applying an adhesive coating to the back side of the wafer;
(6) removing the protection tape from the top side of the wafer;
(7) removing the water soluble or organic solvent soluble material from the dicing lines between the circuits; and
(8) separating the wafer along the dicing lines into individual circuits.

2. The method according to claim 1 in which the water or organic solvent soluble material is a water soluble material selected from the group consisting of polyvinyl alcohol, water-soluble cellulosics, gelatin, starches and polysaccharides, polyethylene oxides, polyvinyl pyrollidone, sulfonated polystyrenes, and polymers derived from ethylenically unsaturated monomers containing hydrophilic groups.

3. The method according to claim 1 in which the wafer back side coating is prepared from a material that hardens to a brittle material.

4. The method according to claim 3 in which the wafer is separated into individual circuits by partial sawing along the dicing streets followed by stretching and breaking the brittle wafer back side coating.
